(19) United States
(12) Patent Application Publication
(10) Pub. No.: US 2025/0122624 A1
(43) Pub. Date: Apr. 17, 2025

(54) GAS FLOW IMPROVEMENT FOR PROCESS CHAMBER

(71) Applicant: Applied Materials, Inc., Santa Clara, CA (US)

(72) Inventors: Vishwas Kumar PANDEY, Madhya Pradesh (IN); Ala MORADIAN, Sunnyvale, CA (US); Lori D. WASHINGTON, San Jose, CA (US)

(21) Appl. No.: 18/484,767

(22) Filed: Oct. 11, 2023

(30) Foreign Application Priority Data
Oct. 28, 2022 (IN) 202241061521

(51) Int. Cl. C23C 16/458; C23C 16/44

(52) U.S. Cl. CPC C23C 16/4585; C23C 16/4408

(57) ABSTRACT

A process chamber including: a chamber body enclosing an interior volume; a substrate support disposed in the interior volume that includes a lower interior volume below the substrate support and an upper interior volume above the substrate support; a first purge gas line configured to provide a first flow of purge gas to the lower interior volume; and a gas flow ring disposed around an outer edge of the substrate support, the gas flow ring comprising: a ring-shaped body; a top surface; a bottom surface; a first overlapping portion extending from a first inner sidewall of the ring-shaped body; and a second overlapping portion extending from a second inner sidewall of the ring-shaped body. The first overlapping portion is spaced apart from and overlies the second overlapping portion to form a gas flow channel that extends from the bottom surface to the top surface of the gas flow ring.

### RELATED APPLICATIONS

This application claims benefit of and priority to Indian Patent Application number 202241061521, filed Oct. 28, 2022, the entire contents of which are incorporated herein by reference.

### BACKGROUND

Embodiments of the present disclosure generally relate to equipment (e.g., a gas flow ring) that provides improvements relating to a purge gas flow in a process chamber. The improvements enable a flowrate of purge gas to be reduced and backside deposition on a substrate support to be reduced.

### DESCRIPTION OF THE RELATED ART

Purge gas is often provided below a substrate support in a process chamber to prevent process gases from entering the volume in the process chamber below the substrate support. When process gases enter the volume below the substrate support problems can occur, such as unintended depositions on surfaces below the substrate support, such as deposition on the backside of the substrate support. These unintended depositions increase the frequency for when the chamber needs to be cleaned. Furthermore, unintended depositions on the backside of the substrate support can reduce the uniformity of the process being performed on a substrate that is positioned on the substrate support. For example, depositions on the backside of the substrate support can reduce the uniformity (e.g., thickness uniformity) of a deposition being performed on a substrate that is positioned on that substrate support.

Generally, a flowrate of purge gas can be increased to reduce the problems associated with process gases entering the volume below the substrate support, such as backside deposition on the substrate support. However, increasing a flowrate of purge gas increases costs as does the downtime for cleaning the chamber mentioned above.

Accordingly, there is a need for improved process chamber equipment that can reduce requirements for purge gas flowrates while not increasing the need for process chamber cleaning.

### SUMMARY

In one embodiment, a process chamber comprising: a chamber body enclosing an interior volume; a substrate support disposed in the interior volume, the interior volume including a lower interior volume below the substrate support and an upper interior volume above the substrate support; a first purge gas line configured to provide a first flow of purge gas to the lower interior volume; and a gas flow ring disposed around an outer edge of the substrate support, the gas flow ring comprising: a ring-shaped body; a top surface; a bottom surface; a first overlapping portion extending from a first inner sidewall of the ring-shaped body; and a second overlapping portion extending from a second inner sidewall of the ring-shaped body, wherein the first overlapping portion is spaced apart from and overlies the second overlapping portion to form a gas flow channel that extends from the bottom surface to the top surface of the gas flow ring.

In another embodiment, a process chamber comprising: a chamber body enclosing an interior volume; a substrate support disposed in the interior volume, the interior volume including a lower interior volume below the substrate support and an upper interior volume above the substrate support; a first purge gas line configured to provide a first flow of purge gas to the lower interior volume; and a gas flow ring disposed around an outer edge of the substrate support, the gas flow ring comprising: a ring-shaped body; a top surface; a bottom surface; and a gas flow channel extending from the bottom surface to the top surface of the gas flow ring, wherein there is no line of sight extending through the channel.

In another embodiment, a process kit for processing a substrate comprising: one or more liners forming a substantially annular structure; and a gas flow ring positioned on an upper surface of the one or more liners, the gas flow ring comprising: a ring-shaped body; a top surface; a bottom surface; a first overlapping portion extending from a first inner sidewall of the ring-shaped body; and a second overlapping portion extending from a second inner sidewall of the ring-shaped body, wherein the first overlapping portion is spaced apart from and overlies the second overlapping portion to form a gas flow channel that extends from the bottom surface to the top surface of the gas flow ring.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic side cross-sectional view of an exemplary process chamber that may be used to practice various embodiments of the deposition process discussed in this disclosure.

FIG. 2A shows a top view of the gas flow ring of FIG. 1 positioned around the outer edge of the substrate support 115 of FIG. 1, according to one embodiment.

FIG. 2B shows a partial side cross-sectional view of a portion of the gas flow ring of FIG. 2A through the section line 2B of FIG. 2A, according to one embodiment.

FIG. 2C shows a top view of an alternative gas flow ring positioned around the outer edge of the substrate support of FIG. 1, according to one embodiment.

FIG. 2D shows a top view of an alternative gas flow ring positioned over a portion of the substrate support of FIG. 1, according to one embodiment.

FIG. 2E shows a partial side cross-sectional view of an alternative gas flow ring including an alternative gas flow channel, according to one embodiment.

FIG. 2F shows a partial side cross-sectional view of an alternative gas flow ring including an alternative gas flow channel, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to equipment that improves purge gas flow within a process chamber. A gas flow ring (also referred to as a preheat ring) can be positioned around a substrate support in the process chamber. The gas flow ring can be spaced apart from the substrate support to allow purge gas provided below the substrate support to flow around the outer edges of the substrate support. Some of the purge gas can flow between the substrate support and the ring while some of the gas can flow through a channel of the ring. For example, the gas flow ring can include a gas flow channel that is configured to allow purge gas to flow from a location below the gas flow ring to a location over the gas flow ring. This gas flow channel can be formed by opposing overlapping portions of the ring. An upper overlapping portion can directly overlie a lower overlapping portion. This overlying arrangement can prevent at least some of the gas from following a single straight line through the channel. The gas flow ring with the overlapping portions has been shown to increase the balance of purge gas flow around a substrate positioned on the substrate support, which can help increase the uniformity of a process (e.g., a deposition) being performed on that substrate. Furthermore, the gas flow ring can decrease an amount of other gases (e.g., precursor gases) that diffuse to regions below the substrate support, which helps decrease unintended depositions, such as depositions on the backside of the substrate support. This reduction in unintended depositions can help reduce the amount of downtime used to clean the process chamber and components, such as the substrate support.

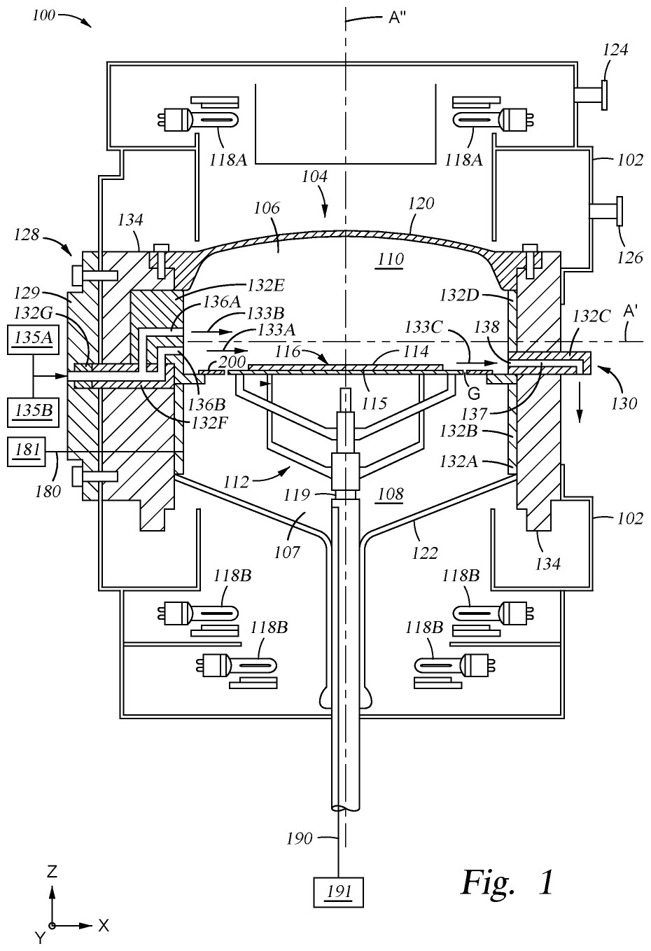

FIG. 1 is a schematic side cross-sectional view of an exemplary process chamber 100 that may be used to practice various embodiments of the deposition process discussed in this disclosure. The process chamber 100 may be used for performing chemical vapor deposition, such as epitaxial deposition and etch processes, as well as other processes.

The chamber 100 includes a housing structure 102 formed of a process resistant material, such as aluminum or stainless steel. The housing structure 102 encloses an inner chamber 104. In some embodiments, the inner chamber 104 can be formed of quartz. The inner chamber 104 can include an upper chamber 106 and a lower chamber 107.

The process chamber 100 further includes a substrate support assembly 112. The substrate support assembly 112 can include a substrate support 115 and a shaft 119 coupled to the substrate support 115. In some embodiments, the substrate support 115 can be a susceptor. In some embodiments, the shaft 119 is coupled to an actuator (not shown) that can be used to rotate the shaft 119. The rotation of the shaft 119 rotates the substrate support 115 allowing a substrate 114 positioned on the substrate support 115 to be rotated during a process, which can increase process uniformity. The substrate 114 can include a processing surface 116 on which a process (e.g., a deposition) is performed. The substrate support 115 can be fabricated from a ceramic material or a graphite material coated with a silicon material, such as silicon carbide.

The upper chamber 106 includes a processing volume 110. The lower chamber 107 includes an inner volume 108. Collectively, the processing volume 110 and the inner volume 108 are referred to as the interior volume. The interior volume includes the space enclosed by the inner chamber 104 (also referred to as chamber body). The processing volume 110 is also referred to as the upper interior volume that is located above the substrate support 115. Similarly, the inner volume 108 is also referred to as the lower interior volume that is located below the substrate support 115.

The process chamber 100 can further include heating equipment, such as upper lamp modules 118A and lower lamp modules 118B. In one embodiment, the upper lamp modules 118A and lower lamp modules 118B are infrared lamps. Radiation from lamp modules 118A and 118B travels through an upper window 120 of upper chamber 106, and through a lower window 122 of the lower chamber 107. In some embodiments, the windows 120, 122 can be formed of quartz. In some embodiments, cooling gases for the upper chamber 106 can enter through an inlet 124 and exit through an outlet 126, and a similar arrangement for cooling gases (not shown) can also be used for the lower chamber 107.

The process chamber 100 can further include a gas distribution assembly 128. Precursor gases can be provided to the processing volume 110 of the inner chamber 104 by the gas distribution assembly 128. Processing byproducts can be removed from processing volume 110 by an exhaust assembly 130, which is typically in communication with a vacuum source (not shown). Precursor reactant gases and etching gases, as well as carrier and vent gases for the chamber 100, can enter through the gas distribution assembly 128 and exit through the exhaust assembly 130.

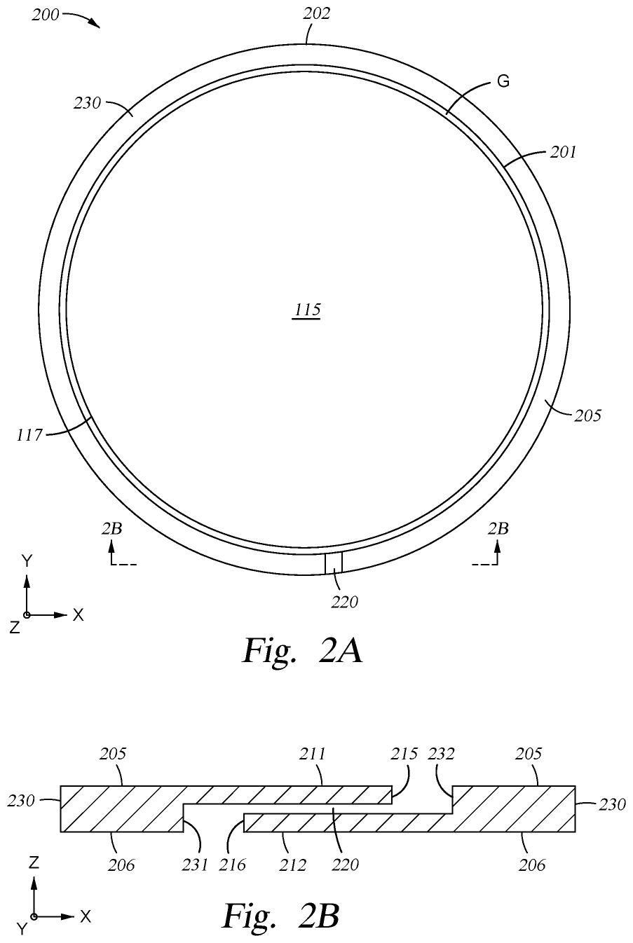

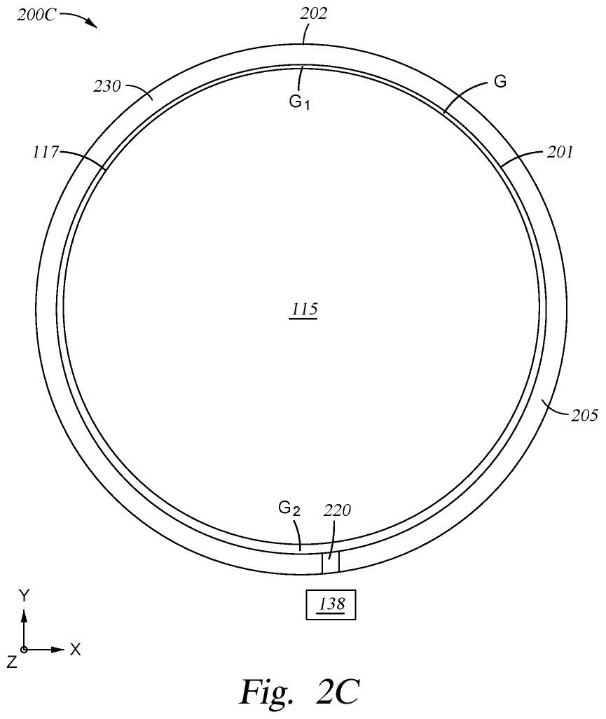

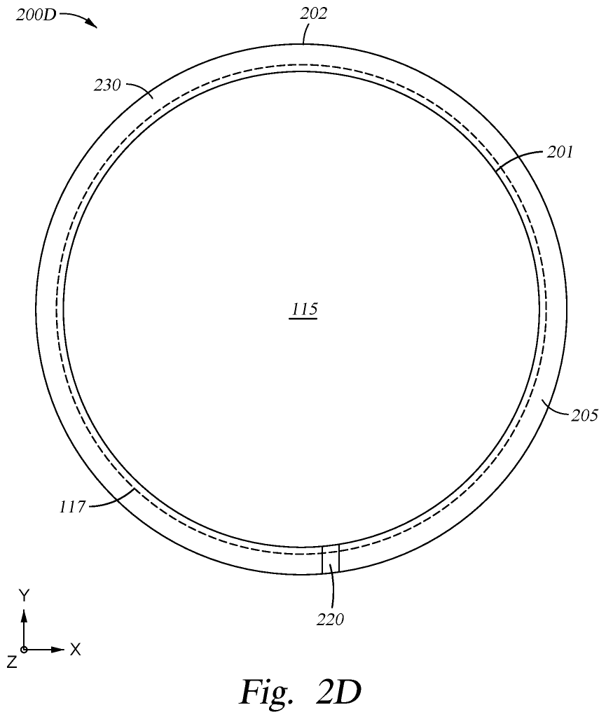

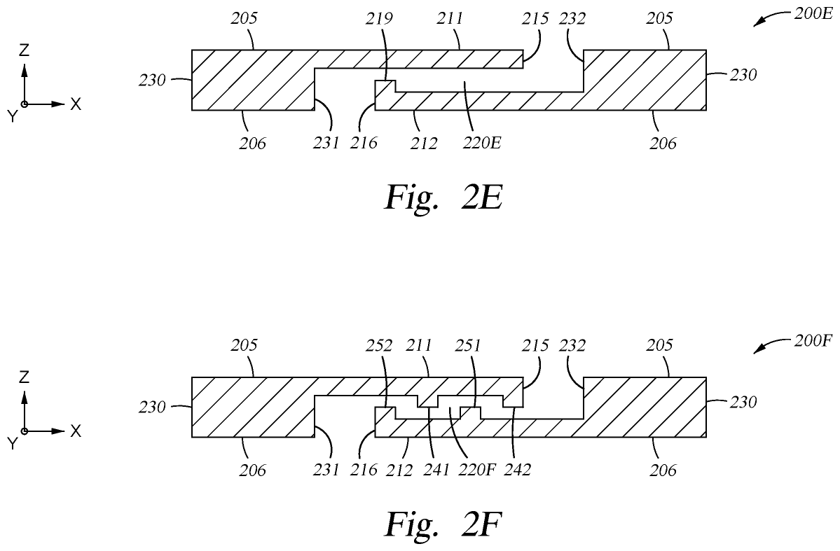

The process chamber 100 can further include a first purge gas line 180 and a second purge gas line 190 to provide one or more purge gases to the inner volume 108 of the lower chamber 107. The first purge gas line 180 can be connected to a first purge gas source 181. The second purge gas line 190 can be connected to a second purge gas source 191. The first purge gas line 180 can enter the inner volume 108 (lower interior volume) at an outer location of the lower chamber 107 through a side of the inner chamber 104. This outer location is closer to an outer edge 117 (FIG. 2A) of the substrate support 115 than the outer location is to a center of the substrate support 115. The second purge gas line 190 can enter into a central location of the inner volume 108 underlying a central portion of the substrate support 115, for example near the shaft 119 of the substrate support assembly 112. A flow of purge gas through the first purge gas line 180 and/or the second purge gas line 190 can be adjusted to balance the purge gas to different portions of the inner volume 108 (e.g., different areas around the edge of the substrate support 115), so that purge gas can prevent precursor gases from the processing volume 110 of the upper chamber 106 from entering into the inner volume 108 of the lower chamber 107.

The chamber 100 also includes multiple liners 132A-132G that shield the processing volume 110 from metallic walls 134 that surround the processing volume 110. In one embodiment, the liners 132A-132G comprise a process kit that covers all metallic components that may be in communication with or otherwise exposed to the processing volume 110.

The one or more gases can be provided to the processing volume 110 from a first gas source 135A and a second gas source 135B through a baffle liner 132G, an inject insert liner assembly 132F and through the one or more openings 136A and 136B formed in an injector liner 132E. The one or more openings 136A and 136B formed in the injector liner 132E are coupled to outlets configured for a laminar flow path 133A or a jetted flow path 133B. In some embodiments, gases coming from the first gas source 135A and the second gas source 135B can be premixed before entering into the chamber and then supplied to the processing volume 110 through a same gas supply line. The openings 136A and 136B may be configured to provide individual or multiple gas flows with varied parameters, such as velocity, density, or composition. In one embodiment, the openings 136A and 136B may be distributed around the gas distribution assembly 128.

Each of the flow paths 133A, 133B can be configured to flow across an axis A′ towards an exhaust liner 132D. The axis A′ is substantially normal to a longitudinal axis A″ of the chamber 100. The flow paths 133A, 133B flow can be directed towards an exhaust flow path 133C that is directed towards an exhaust inlet 138 of an exhaust plenum 137 formed in an exhaust liner 132C. The plenum 137 is coupled to an exhaust or vacuum pump (not shown). The inject insert liner assembly 132F may be disposed through and partially supported by an inject cap 129. Furthermore, although only two gas sources 135A, 135B are shown in FIG. 1, process chamber 100 can be adapted include three or more gas sources.

The process chamber 100 further includes a gas flow ring 200 (also referred to as a preheat ring) disposed around the substrate support 115. In some embodiments the bottom surface of the gas flow ring 200 can be positioned on one or more liners (e.g., liner 132B). The gas flow ring 200 can be spaced apart from an outer edge 117 (see FIG. 2A) of the substrate support 115 by a gap G. The gas flow ring 200 can be used to control a flow of purge gas in the process chamber 100. Purge gas provided from the purge gas lines 180, 190 can flow into the inner volume 108 of the lower chamber 107, through the gap G to the processing volume 110 of the upper chamber 106, and then out of the processing volume 110 through the exhaust assembly 130. The gas flow ring 200 further includes a gas flow channel 220 (see FIGS. 2A, 2B) that also allows purge gas to flow along a similar path.

The gap G can have a width in the X-direction of FIG. 1 (also referred to as a radial direction from the center of the substrate support 115) from about 0.25 mm to about 12 mm, such as from about 0.5 mm to about 6.5 mm. In some embodiments, the gap G can extend around the outer edge 117 (see FIG. 2A) of the substrate support 115 with a size that is substantially constant (i.e., within 2.5% of the average size around the whole substrate support 115. In other embodiments (see FIG. 2C), the size of the gap vary substantially around the substrate support 115.

FIG. 2A shows a top view of the gas flow ring 200 positioned around the outer edge 117 of the substrate support 115 of FIG. 1, according to one embodiment. FIG. 2B shows a partial side cross-sectional view of a portion of the gas flow ring 200 of FIG. 2A through the section line 2B of FIG. 2A, according to one embodiment.

The gas flow ring 200 includes a ring-shaped body 230. The ring-shaped body 230 can form most of the gas flow ring 200. For example, in some embodiments the ring-shaped body 230 can form greater than 90% of the total circumference of the gas flow ring 200. The gas flow ring 200 further includes an inner edge 201 and an outer edge 202. The inner edge 201 of the gas flow ring 200 is spaced apart from the outer edge 117 of the substrate support 115 by the gap G described above. The gas flow ring 200 further includes a gas flow channel 220 that can allow purge gas to flow from below the substrate support 115 to above the substrate support 115.

The gas flow ring 200 includes a top surface 205 and a bottom surface 206 as shown in FIG. 2B. The ring-shaped body 230 can further include a first inner sidewall 231 and a second inner sidewall 232. The first inner sidewall 231 can face the second inner sidewall 232. The gas flow ring 200 further includes a first overlapping portion 211 and a second overlapping portion 212. The first overlapping portion 211 can extend from the first inner sidewall 231 to a leading edge 215 of the first overlapping portion 211. The second overlapping portion 212 can extend from the second inner sidewall 232 to a leading edge 216 of the second overlapping portion 212. The first overlapping portion 211 can overlie (i.e., only vertical separation) the second overlapping portion 212. The space between the first overlapping portion 211 and the second overlapping portion 212 can form a portion of the gas flow channel 220. Overall, the gas flow channel 220 is formed by the space created by the separation of (1) the first inner sidewall 231 and the first overlapping portion 211 from (2) the second inner sidewall 232 and the second overlapping portion 212.

The leading edge 215 of the first overlapping portion 211 can be horizontally spaced apart from the second inner sidewall 232 by a distance from about 0.25 mm to about 20 mm, such as from about 0.5 mm to about 10 mm. Similarly, the leading edge 216 of the second overlapping portion 212 can be horizontally spaced apart from the first inner sidewall 231 by a distance from about 0.25 mm to about 20 mm, such as from about 0.5 mm to about 10 mm. The first overlapping portion 211 can be vertically spaced apart from the second overlapping portion 212 by a distance from about 0.25 mm to about 8 mm, such as from about 0.5 mm to about 4 mm. In some embodiments, the first inner sidewall 231 can be horizontally spaced apart from the second inner sidewall 232 by a distance from about 4.5 mm to about 30 mm.

Referring to FIGS. 1 and 2B, depending on the design of the gas flow channel 220, the gas flow ring 200 can completely prevent or substantially reduce an amount of gas that can flow from the inner volume 108 of the lower chamber 107 to the processing volume 110 of the upper chamber 106 in a straight line path. In some embodiments of the gas flow ring 200, there is no straight line path (i.e., no line of sight) from the inner volume 108 of the lower chamber 107 to the processing volume 110 of the upper chamber 106. In some other embodiments, there is no line of sight path through the channel 220 for at least some radial locations for the channel 220, where a center of the gas flow ring 200 is used to determine radial distances. In some embodiments, there is no line of sight path through the channel 220 for at least some locations along the inner edge 201 of the gas flow ring 200.

FIG. 2C shows a top view of an alternative gas flow ring 200C positioned around the outer edge 117 of the substrate support 115 of FIG. 1, according to one embodiment. The arrangement of the alternative gas flow ring 200C and the substrate support 115 is the same as described above for FIG. 2A except that the size of the gap G between the gas flow ring 200C and the outer edge 117 of the substrate support 115 varies substantially around the outer edge 117 of the substrate support 115. This variation in the size of the gap G can provide more control over the flow of purge gas around the outer edge 117 of the substrate support 115. For example, a smaller gap can be used further from the exhaust inlet 138 and closer to the gas inlet openings 136A, 136B (see FIG. 1) to prevent disturbances to the gas flow passing over wafer and to cause less dilution of precursor gases. Reduced dilution of precursor gases can increase growth rates for depositions and increase throughput. In some of these embodiments, the gap G at a first location around the substrate support 115 can be from about 10% to about 80%, such as from about 20% to about 50% of the size of the gap G at a second location around the substrate support 115. For example, as shown in FIG. 2C, the size of the gap G at a first location G1 is substantially smaller (e.g., more than 50% smaller) than the size of the gap G at a second location G2. In some embodiments, the gas flow ring 200C can be positioned around the substrate support 115, so that the gap G has a larger size at locations closer to the exhaust inlet 138 (e.g., location G2) relative to locations further from the exhaust inlet 138 (e.g., location G1), for example near the gas inlet side.

In some embodiments, the gas flow ring 200C is the same as the gas flow ring 200A, and the gas flow ring 200C is positioned so that the center of the gas flow ring 200C is not aligned with the center of the substrate support 115. In other embodiments, the gas flow ring 200C is physically different than the gas flow ring 200 described above. For example, in one embodiment, the inner edge 201 of the gas flow ring 200C can have a non-circular shape to control the size of the gap around the outer edge 117 of the substrate support 115.

FIG. 2D shows a top view of an alternative gas flow ring 200D positioned over a portion of the substrate support 115 of FIG. 1, according to one embodiment. As shown, a portion of the gas flow ring 200D overlies a portion of the top surface of the substrate support 115. The outer edge 117 of the substrate support 115 is shown as a dashed line to indicate the position of the hidden outer edge 117 of the substrate support 115 in the top view of FIG. 2D even though the outer edge 117 would not be visible in arrangement shown in FIG. 2D. The gas flow ring 200D is positioned at a different vertical location relative to the substrate support 115. In some embodiments, the amount of overhang of the gas flow ring 200D over the substrate support 115 can vary around the outer edge 117 of the substrate support 115. Although the vertical gap between the gas flow ring 200D and the substrate support 115 is not shown, this gap can have a similar vertical size to the horizontal size of the gap G described above in reference to FIGS. 1 and 2A.

The addition of the gas flow channel 220 to the gas flow rings described above allows for increased control of the purge gas in the process chamber compared to previous gas flow rings that were configured to allow a fully open straight line path (e.g., straight-line vertical path) from below the gas flow ring to above the gas flow ring. The increased control of the purge gas in the process chamber provided by these gas flow rings reduces the amount of precursor gas that can enter the lower interior volume of the process chamber (i.e., below the substrate support) for a given flowrate of purge gas, which can prevent unintended depositions on components in the lower chamber, such as on the backside of the substrate support 115. The purge gas rings described above also improve the uniformity of the flow of purge gas around the gas flow ring and around the substrate being processed. Furthermore, this improved uniformity can be achieved at lower flow rates of purge gas compared to when conventional purge gas rings are used. In one example, a 50% reduction in use of purge gas was achieved using a gas flow ring with a gas flow channel (e.g., gas flow channel 220) having the features described above.

The improved uniformity of purge gas around the substrate can also improve the uniformity of a process (e.g., a deposition) being performed on the substrate. Additionally, because the gas flow ring improves the uniformity at lower flow rates of purge gas compared to conventional gas flow rings, the purge gas rings described above also allow cost savings to be achieved through use of less purge gas. Furthermore, because less precursor diffuses to regions in the lower interior volume (e.g., below the substrate support), the concentration of precursor gases above the substrate support remain higher, which can allow processes (e.g., depositions) to be completed more quickly, and there is less precursor gas wasted.

FIG. 2E shows a partial side cross-sectional view of an alternative gas flow ring 200E including a gas flow channel 220E, according to one embodiment. The gas flow ring 200E can be the same as the gas flow ring 200 described above except that the gas flow ring 200E includes the gas flow channel 220E as opposed to the gas flow channel 220 described above in reference to FIG. 2A and FIG. 2B. The gas flow channel 220E is different than the gas flow channel 220 due to a protrusion 219 extending into the channel 220E from the second overlapping portion 212 towards the first overlapping portion 211. The protrusion 219 is shown at the leading edge 216 of the second overlapping portion 212, but can also be located at different positions on the second overlapping portion 212. Alternatively, the protrusion 219 can be located on the first overlapping portion 211. The protrusion 219 can further restrict the flow of gas through the channel 220E relative to the flow of gas through the channel 220 shown in FIG. 2B, which can allow for additional control of the flow of purge gas around the substrate support 115.

FIG. 2F shows a partial side cross-sectional view of an alternative gas flow ring 200F including a gas flow channel 220F, according to one embodiment. The gas flow ring 200F can be the same as the gas flow ring 200 described above except that the gas flow ring 200F includes the gas flow channel 220F as opposed to the gas flow channel 220 described above in reference to FIG. 2A and FIG. 2B. The gas flow channel 220F is different than the gas flow channel 220 due to multiple protrusions extending into the channel 220F from the overlapping portions 211, 212. The first overlapping portion 211 includes a first protrusion 241 and a second protrusion 242 extending downwards in the Z-direction towards the second overlapping portion 212. The second overlapping portion 212 includes a first protrusion 251 and a second protrusion 252 extending upwards in the Z-direction towards the first overlapping portion 211. To further restrict flow of gas through the gas flow channel 220F, the size of the protrusions can be increased. The protrusions 241, 242, 251, 252 can further restrict the flow of gas through the channel 220F relative to the flow of gas through the channel 220 shown in FIG. 2B, which can allow for additional control of the flow of purge gas around the substrate support 115. In some embodiments, more (e.g., six or ten protrusions) or less protrusions (e.g., two or three protrusions) can be used. In one embodiment including two protrusions, each overlapping portion 211, 212 includes a protrusion extending into the gas flow channel at the corresponding leading edge 215, 216.

Each protrusion in the gas flow channel of FIGS. 2E and 2F can make the gas flow path more tortuous, which can further prevent the diffusion of precursor gases from above the substrate support 115 (see FIG. 1) to regions below the substrate support 115. Because this diffusion of precursor gas is reduced by the protrusions, less purge gas can be used to achieve the same results, which provides a cost benefit for production. The reduced diffusion of precursor gas also reduces the amount of downtime used for cleaning the chamber as well as increases the concentration of purge gas over the substrate, which increases the efficiency of the process as described above.

While the foregoing is directed to examples of the present disclosure, other and further examples of the disclosure may be devised without departing from the basic scope thereof, and the scope thereof is determined by the claims that follow.

What is claimed is:

1. A process chamber comprising:
a chamber body enclosing an interior volume;
a substrate support disposed in the interior volume, the interior volume including a lower interior volume below the substrate support and an upper interior volume above the substrate support;
a first purge gas line configured to provide a first flow of purge gas to the lower interior volume; and
a gas flow ring disposed around an outer edge of the substrate support, the gas flow ring comprising:
a ring-shaped body; a top surface; a bottom surface; a first overlapping portion extending from a first inner sidewall of the ring-shaped body; and a second overlapping portion extending from a second inner sidewall of the ring-shaped body, wherein
the first overlapping portion is spaced apart from and overlies the second overlapping portion to form a gas flow channel that extends from the bottom surface to the top surface of the gas flow ring.

2. The process chamber of claim 1, wherein a leading edge of the first overlapping portion is horizontally spaced apart from the second inner sidewall by a distance from about 0.5 mm to about 10 mm.

3. The process chamber of claim 1, wherein the first overlapping portion is vertically spaced apart from the second overlapping portion by a distance from about 0.5 mm to about 4 mm.

4. The process chamber of claim 1, wherein the gas flow ring is spaced apart from an outer edge of the substrate support by a gap.

5. The process chamber of claim 4, wherein a size of the gap at a first location around the outer edge of the substrate support is from about 10% to about 50% relative to a size of the gap at a second location around the outer edge of the substrate support.

6. The process chamber of claim 1, wherein
the first overlapping portion or the second overlapping portion includes a first protrusion extending into the gas flow channel towards the other overlapping portion.

7. The process chamber of claim 1, wherein
the first overlapping portion includes a first protrusion extending into the gas flow channel towards the second overlapping portion, and
the second overlapping portion includes a second protrusion extending into the gas flow channel towards the first overlapping portion.

8. The process chamber of claim 1, wherein at least of portion of the gas flow ring overlies a portion of a top surface of the substrate support.

9. The process chamber of claim 1, further comprising a second purge gas line configured to provide a second flow of purge gas to the lower interior volume, wherein
the first purge gas line is configured to provide the first flow of purge gas to an outer location in the lower interior volume, and
the second purge gas line is configured to provide the second flow of purge gas to a central location in the lower interior volume underlying a central portion of the substrate support, wherein the outer location is closer to an outer edge of the substrate support than the outer location is to a center of the substrate support.

10. A process chamber comprising:
a chamber body enclosing an interior volume;
a substrate support disposed in the interior volume, the interior volume including a lower interior volume below the substrate support and an upper interior volume above the substrate support;
a first purge gas line configured to provide a first flow of purge gas to the lower interior volume; and
a gas flow ring disposed around an outer edge of the substrate support, the gas flow ring comprising:
a ring-shaped body; a top surface; a bottom surface; and a gas flow channel extending from the bottom surface to the top surface of the gas flow ring, wherein there is no line of sight extending through the gas flow channel.

11. The process chamber of claim 10, wherein a width of the gas flow channel at the top surface of gas flow ring is from about 0.5 mm to about 10 mm.

12. The process chamber of claim 10, wherein the gas flow ring includes a first overlapping portion and a second overlapping portion, the first overlapping portion is spaced apart from the second overlapping portion to form the gas flow channel, and the first overlapping portion is vertically spaced apart from the second overlapping portion by a distance from about 0.5 mm to about 4 mm.

13. The process chamber of claim 10, wherein the gas flow ring is spaced apart from an outer edge of the substrate support by a gap.

14. The process chamber of claim 13, wherein a size of the gap is substantially constant around the outer edge of the substrate support.

15. The process chamber of claim 13, wherein a size of the gap at a first location around the outer edge of the substrate support is from about 10% to about 50% relative to a size of the gap at a second location around the outer edge of the substrate support.

16. The process chamber of claim 15, further comprising an exhaust inlet, wherein the second location is closer to the exhaust inlet than the first location is to the exhaust inlet.

17. The process chamber of claim 10, wherein at least of portion of the gas flow ring overlies a portion of a top surface of the substrate support.

18. The process chamber of claim 10, further comprising a second purge gas line configured to provide a second flow of purge gas to the lower interior volume, wherein
the first purge gas line is configured to provide the first flow of purge gas to an outer location in the lower interior volume, and
the second purge gas line is configured to provide the second flow of purge gas to a central location in the lower interior volume underlying a central portion of the substrate support, wherein the outer location is closer to an outer edge of the substrate support than the outer location is to a center of the substrate support.

19. A process kit for processing a substrate comprising:
one or more liners forming a substantially annular structure; and
a gas flow ring positioned on an upper surface of the one or more liners, the gas flow ring comprising:
a ring-shaped body; a top surface; a bottom surface; a first overlapping portion extending from a first inner sidewall of the ring-shaped body; and a second overlapping portion extending from a second inner sidewall of the ring-shaped body, wherein
the first overlapping portion is spaced apart from and overlies the second overlapping portion to form a gas flow channel that extends from the bottom surface to the top surface of the gas flow ring.

20. The process kit of claim 19, wherein there is no line of sight extending through the gas flow channel.
